(19) United States
(12) Patent Application Publication
(10) Pub. No.: US 2024/0290775 A1
(43) Pub. Date: Aug. 29, 2024

(54) ELECTROSTATIC DISCHARGE PROTECTION DEVICE

(71) Applicant: MEDIATEK INC., Hsinchu City (TW)

(72) Inventor: Shih-Chun YEN, Hsinchu City (TW)

(21) Appl. No.: 18/422,055

(22) Filed: Jan. 25, 2024

Related U.S. Application Data
(60) Provisional application No. 63/486,486, filed on Feb. 23, 2023.

(51) Int. Cl. H01L 27/02; H01L 29/40

(52) U.S. Cl. CPC H01L 27/0259; H01L 27/0207; H01L 29/404

(57) ABSTRACT

An electrostatic discharge protection device is provided. The electrostatic discharge protection device includes a P-type semiconductor substrate, N-type and P-type well regions, first and second N-type doped regions, a first P-type doped region and a first conductive plate. The N-type and P-type well regions are located in the P-type semiconductor substrate and are adjacent to each other. The first N-type doped region located on the N-type well region is spaced apart from the second N-type doped region located on the P-type well region by an isolation feature. The first P-type doped region located on the P-type well region is spaced apart from the second N-type doped region. The first conductive plate overlaps the isolation feature. The first N-type doped region and the first conductive plate are electrically connected to a power-supply terminal. The second N-type and first P-type doped regions are electrically connected to a ground terminal.

### CROSS REFERENCE TO RELATED APPLICATIONS

This application claims the benefit of U.S. Provisional Application No. 63/486,486, filed Feb. 23, 2023, the entirety of which is incorporated by reference herein.

### BACKGROUND OF THE INVENTION

### Field of the Invention

The present disclosure relates to an electrostatic discharge protection device, and, in particular, to the structure and layout of an electrostatic discharge protection device having low trigger voltage and low on-resistance.

### Description of the Related Art

Electrostatic discharge (ESD) is a phenomenon that releases and transfers charges between a semiconductor device (e.g., a semiconductor chip) and an external object (e.g., a human body). In an ESD, a large amount of charge is released in a short time, and so the energy from an ESD is much higher than the bearing capacity of the semiconductor device, and this may result in a temporary functional failure or even permanent damage to the semiconductor device. Therefore, an ESD clamp circuit is provided in semiconductor devices to offer an electrostatic discharge path that effectively protects the semiconductor device, so that the reliability and service life of the semiconductor device can be improved. However, the trigger voltage and on-resistance of the ESD clamp circuit are required to be further reduced.

### BRIEF SUMMARY OF THE INVENTION

An embodiment of the disclosure provides an electrostatic discharge protection device. The electrostatic discharge protection device includes a P-type semiconductor substrate, an N-type well region, a first N-type doped region, a P-type well region, a second N-type doped region, a first P-type doped region and a first conductive plate. The N-type well region is located in the P-type semiconductor substrate. The first N-type doped region is located on the N-type well region. The P-type well region is located in the P-type semiconductor substrate and is adjacent to the N-type well region. The second N-type doped region is located on the P-type well region. The first N-type doped region is spaced apart from the second N-type doped region by an isolation feature. The first P-type doped region is located on the P-type well region. The first P-type doped region and the second N-type doped region are spaced apart from each other. The first conductive plate is disposed overlapping the isolation feature. The first N-type doped region and the first conductive plate are electrically connected to a power-supply terminal. The second N-type doped region and the first P-type doped region are electrically connected to a ground terminal.

An embodiment of the disclosure provides an electrostatic discharge protection device. The electrostatic discharge protection device includes a P-type semiconductor substrate and an N-type field oxide field-effect transistor. The N-type field oxide field-effect transistor includes an N-type well region, a P-type well region, a first N-type source/drain doped region, a second N-type source/drain doped region, an isolation feature, a gate electrode and a first P-type bulk doped region. The N-type well region and the P-type well region are located in the P-type semiconductor substrate and are adjacent to each other. The first N-type source/drain doped region is located on the N-type well region. The second N-type source/drain doped region is located on the P-type well region. The isolation feature is located in the P-type semiconductor substrate and between the first N-type source/drain doped region and the second N-type source/drain doped region. The gate electrode includes a first conductive plate disposed directly above the isolation feature and the P-type well region. The P-type bulk doped region is located on the P-type well region and spaced apart from the second N-type source/drain doped region. The first N-type source/drain doped region is electrically connected to the gate electrode. The second N-type source/drain doped region is electrically connected to the P-type bulk doped region.

### BRIEF DESCRIPTION OF THE DRAWINGS

The present invention can be more fully understood by reading the subsequent detailed description and examples with references made to the accompanying drawings, wherein:

FIG. 1 is a schematic connection diagram of an electrostatic discharge protection device in accordance with some embodiments of the disclosure;

FIG. 2A is a schematic layout of the electrostatic discharge protection device of FIG. 1 in accordance with some embodiments of the disclosure;

FIG. 2B is a schematic layout of the electrostatic discharge protection device of FIG. 1 in accordance with some embodiments of the disclosure;

FIG. 2C is a schematic layout of the electrostatic discharge protection device of FIG. 1 in accordance with some embodiments of the disclosure;

FIG. 2D is a schematic layout of the electrostatic discharge protection device of FIG. 1 in accordance with some embodiments of the disclosure;

FIG. 3 is a schematic cross-sectional view of the electrostatic discharge protection device of FIGS. 2A, 2B, 2C and 2D in accordance with some embodiments of the disclosure;

FIG. 4 is a schematic cross-sectional view of the electrostatic discharge protection device of FIGS. 2A, 2B, 2C and 2D in accordance with some embodiments of the disclosure;

FIG. 5A is a schematic layout of the electrostatic discharge protection device of FIG. 1 in accordance with some embodiments of the disclosure;

FIG. 5B is a schematic layout of the electrostatic discharge protection device of FIG. 1 in accordance with some embodiments of the disclosure;

FIG. 6 is a schematic cross-sectional view of the electrostatic discharge protection device of FIGS. 5A and 5B in accordance with some embodiments of the disclosure;

FIG. 7 is a schematic cross-sectional view of the electrostatic discharge protection device of FIGS. 5A and 5B in accordance with some embodiments of the disclosure;

FIG. 8A is a schematic layout of the electrostatic discharge protection device of FIG. 1 in accordance with some embodiments of the disclosure;

FIG. 8B is a schematic layout of the electrostatic discharge protection device of FIG. 1 in accordance with some embodiments of the disclosure;

FIG. 9 is a schematic cross-sectional view of the electrostatic discharge protection device of FIGS. 8A and 8B in accordance with some embodiments of the disclosure;

FIG. 10A is a schematic layout of the electrostatic discharge protection device of FIG. 1 in accordance with some embodiments of the disclosure;

FIG. 10B is a schematic layout of the electrostatic discharge protection device of FIG. 1 in accordance with some embodiments of the disclosure; and

FIG. 11 is a schematic cross-sectional view of the electrostatic discharge protection device of FIGS. 10A and 10B in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

Electrostatic discharge (ESD) clamp circuit arranged between a power-supply terminal VDD and a ground terminal VSS is usually provided to protect the internal circuit. However, the conventional ESD clamp circuit has long discharging current path from the power-supply terminal VDD to the ground terminal VSS, thereby increasing trigger voltage and on-resistance (Ron) and affecting the performance of the ESD clamp circuit.

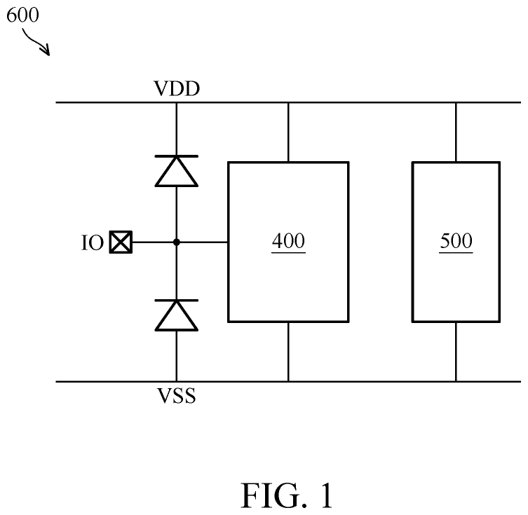

FIG. 1 is a schematic connection diagram of an electrostatic discharge (ESD) protection device 500 disposed in a system 600 in accordance with some embodiments of the disclosure. The system 600 includes an internal circuit 400 and the electrostatic discharge (ESD) protection device 500 (including ESD protection devices 500A, 500B, 500A′, 500B′, 500C, 500D and 500E shown in the following figures) used to protect the internal circuit 400. The internal circuit 400 is electrically connected to an input/output terminal IO, a power-supply terminal VDD and a ground terminal VSS of the system 600. The electrostatic discharge (ESD) protection device 500 is electrically connected between the power-supply terminal VDD and the ground terminal VSS of the system 600. The electrostatic discharge (ESD) protection device 500 may serve as a power clamp device to prevent an electrostatic discharge current from flowing through the internal circuit 400.

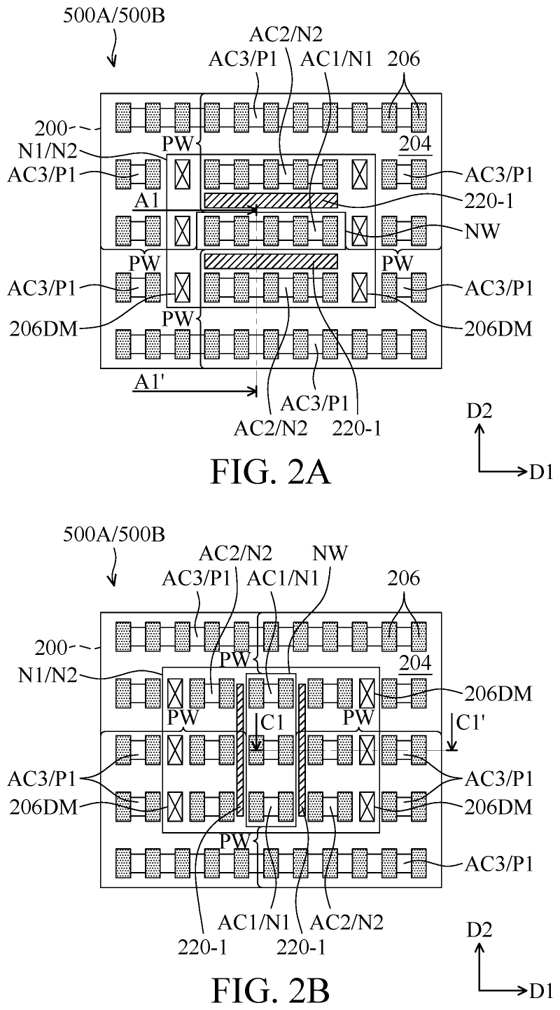

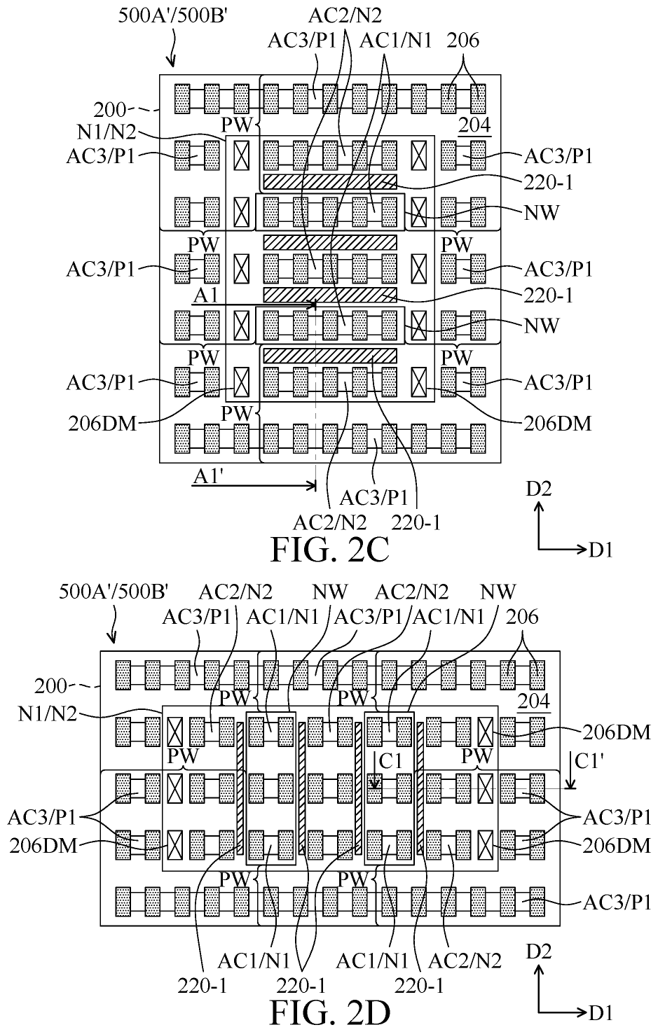

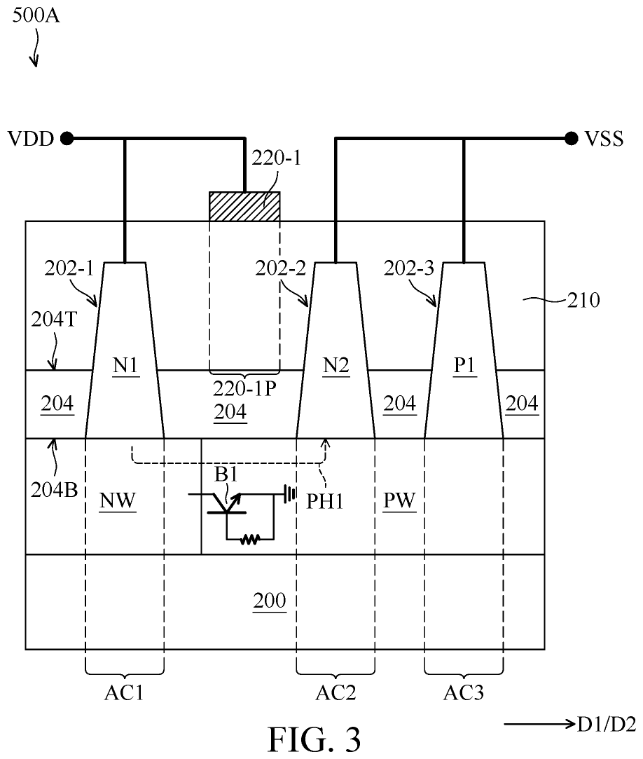

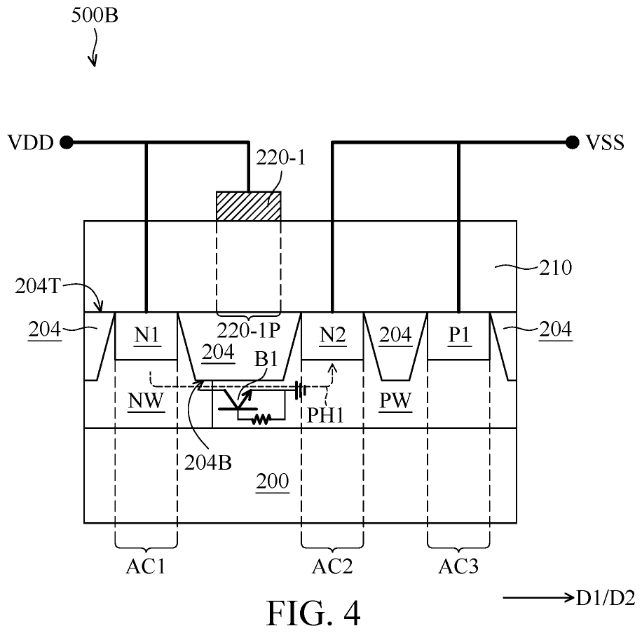

FIG. 2A is a schematic layout of the electrostatic discharge protection device 500A/500B of FIG. 1 in accordance with some embodiments of the disclosure. FIG. 2B is another schematic layout of the electrostatic discharge protection device 500A/500B of FIG. 1 in accordance with some embodiments of the disclosure. FIGS. 2A and 2B may also serve as schematic plane views of the electrostatic discharge protection device 500A/500B in accordance with some embodiments of the disclosure. FIGS. 3 and 4 are schematic cross-sectional views of the electrostatic discharge protection devices 500A and 500B along lines A1-A1′ and C1-C1′ of FIGS. 2A and 2B in accordance with some embodiments of the disclosure. FIG. 2C is a schematic layout of the electrostatic discharge protection device 500A′/500B′ of FIG. 1 in accordance with some embodiments of the disclosure. FIG. 2D is another schematic layout of the electrostatic discharge protection device 500A′/500B′ of FIG. 1 in accordance with some embodiments of the disclosure. FIGS. 2C and 2D may also serve as schematic plane views of the electrostatic discharge protection device 500A′/500B′ in accordance with some embodiments of the disclosure. FIGS. 3 and 4 are schematic cross-sectional views of the electrostatic discharge protection devices 500A′ and 500B′ along lines A1-A1′ and C1-C1′ of FIGS. 2C and 2D in accordance with some embodiments of the disclosure. In some embodiments, the electrostatic discharge protection device 500A/500A′/500B/500B′ may be fabricated by fin field-effect transistor (finFET) processes (FIG. 3) or planar metal-oxide-semiconductor field-effect transistor (MOSFET) processes (FIG. 4). For illustration, dielectric layers 210, 230 (shown in FIGS. 3, 4, 6, 7, 9 and 11) formed over a P-type semiconductor substrate 200 (FIGS. 2A, 2B, 2C and 2D) are hidden in FIGS. 2A, 2B, 2C and 2D. For illustration, polysilicon gate structures 206 formed over a P-type semiconductor substrate 200 (FIGS. 2A, 2B, 2C and 2D) are hidden in FIGS. 3 and 4.

As shown in FIGS. 2A, 2B, 2C and 2D, the ESD protection device 500A/500A′/500B/500B′ includes the P-type semiconductor substrate 200. In some embodiments, the P-type semiconductor substrate 200 includes one or more first active regions AC1, one or more second active regions AC2 and one or more third active regions AC3 defined by isolation features 204 such as shallow trench isolation trench isolations (STIs). For example, as shown in FIGS. 2A and 2B, the ESD protection device 500A/500B may include one first active region AC1 sandwiched between adjacent two second active regions AC2. In addition, the first active region AC1 and the second active regions AC2 are surrounded by a plurality of the third active regions AC3. For example, as shown in FIGS. 2C and 2D, the ESD protection device 500A/500B may include multiple (at least two or more than two) first active regions AC1. Each of the in a first N-type doped region N1 is sandwiched between adjacent two second active regions AC2. In addition, the first active region AC1 and the second active regions AC2 are surrounded by a plurality of the third active regions AC3.

In some embodiments as shown in FIGS. 2A and 2C, the first active region AC1, the second active regions AC2 and the third active regions AC3 may extend along a direction D1 and separated from one another along a direction D2 that is different from the direction D1. In addition, the first active region AC1 (or the second active regions AC2) is separated from third active regions AC3 along the directions D1 and D2. In some embodiments as shown in FIGS. 2B and 2D, the first active region AC1, the second active regions AC2 and the third active regions AC3 may extend along the direction D1 and separated from one another along the direction D2. In the cross-sectional views shown in FIGS. 3 and 4, in the ESD protection device 500A/500B, the second active regions AC2 may be disposed between the first active region AC1 and the third active regions AC3. In the ESD protection device 500A′/500B′ shown in FIGS. 2C and 2D, some of the second active regions AC2 may be disposed between the adjacent two first active regions AC1, and others may be disposed between the first active region AC1 and the third active regions AC3. The second active regions AC2 may be separated from the first active region AC1 and the third active regions AC3 by the isolation features 204.

As shown in FIGS. 2A, 2B, 2C, 2D and 3, in the fin field-effect transistor (finFET) platform, the ESD protection device 500A/500A′ may further include fins 202-1, 202-2 and 202-3 protruding from the P-type semiconductor substrate 200. The fins 202-1, 202-2 and 202-3 may be parallel to one another and surrounded by the isolation features 204. In some embodiments, the fin 202-1 may serve as the first active region AC1, the fin 202-2 may serve as the second active region AC2, and the fin 202-3 may serve as the third active region AC3. As shown in FIG. 4, in the planar metal-oxide-semiconductor field-effect transistor (MOSFET) platform, the first active regions AC1, the second active regions AC2 and the third active regions AC3 of the ESD protection device 500B/500B′ are separated portions of the P-type semiconductor substrate 200 and surrounded by the isolation features 204.

The ESD protection device 500A/500A′/500B/500B′ may include an N-type well region NW, a first N-type doped region N1, a P-type well region PW, a second N-type doped region N2, an isolation feature 204, a first P-type doped region P1 and a conductive plate 220. The N-type well region NW and the P-type well region PW are located in the P-type semiconductor substrate 200. Each of the N-type well region NW and the P-type well region PW has at least a heavily doped region formed thereon. For example, the first N-type doped region N1 (i.e., a first N-type heavily doped region N1) is located on the N-type well region NW. The second N-type doped region N2 (i.e., a second N-type heavily doped region N2) and the first P-type doped region P1 (i.e., a first P-type heavily doped region P1) are located on the P-type well region PW. In some embodiments, the first N-type doped region N1 and the second N-type doped region N2 may have the same doping concentration.

As shown in FIGS. 2A, 2B, 2C, 2D, 3 and 4, the N-type well region NW and the P-type well region PW are adjacent to each other. In the plane view as shown in FIGS. 2A, 2B, 2C and 2D, the N-type well region NW is surrounded by the P-type well region PW. The first N-type doped region N1, the second N-type doped region N2 and the first P-type doped region P1 may extend along the direction D1 (corresponding to the arrangements of the active regions AC1, AC2 and AC3). The first N-type doped region N1 is spaced apart from the second N-type doped region N2 by the isolation feature 204 between the N-type well region NW and the P-type well region PW. In other words, the first N-type doped region N1 and the second N-type doped region N2 are located on opposite sides of the isolation feature 204 overlapping the N-type well region NW and the P-type well region PW. In addition, the second N-type doped region N2 and the first P-type doped region P1 are spaced apart from each other by the isolation feature 204 located within the P-type well region PW. In the ESD protection device 500A/500B, the second N-type doped region N2 may be located between the first N-type doped region N1 and the first P-type doped region P1. In the ESD protection device 500A′/500B′, some of the second N-type doped regions N2 may be located between the first N-type doped region N1 and the first P-type doped region P1, and others may be located between the adjacent two first N-type doped regions N1.

As shown in FIGS. 2A, 2B, 2C and 2D, the ESD protection device 500A/500A′/500B/500B′ may further include polysilicon gate structures 206 formed on the active regions AC1, AC2 and AC3. The polysilicon gate structures 206 are arranged along the direction D1 and extend along the direction D2. In addition, the polysilicon gate structures 206 cover portions of the active regions AC1, AC2 and AC3. In the fin field-effect transistor (finFET) platform, the polysilicon gate structures 206 may cover the top surfaces and side surfaces (not shown) of the fins 202-1, 202-2 and 202-3 (i.e., the active regions AC1, AC2 and AC3). In some embodiments, the polysilicon gate structures 206 disposed on the active regions AC1, AC2 and AC3 may form various active or passive devices, such as transistors, diodes, resistors, capacitors, inductors, etc. In some embodiments, the ESD protection device 500A/500A′/500B/500B′ may further include dummy polysilicon gate structures 206DM on the isolation features 204 between the active regions AC1, AC2 and AC3 to achieve more uniform pattern density across the wafer (or the chip), thereby reducing pattern-loading effects.

As shown in FIGS. 3 and 4, the ESD protection device 500A/500A′/500B/500B′ may further include a dielectric layer 210 covering the P-type semiconductor substrate 200. In some embodiments, the dielectric layer 210 may include an interlayer dielectric (ILD) layer, an intermetal dielectric (IMD) layer or a dielectric multi-layer structure composed of the ILD layer and one or more IMD layers. The dielectric layer 210 may include borophosphosilicate glass (BPSG), fused silica glass (FSG), phosphosilicate glass (PSG), boron doped silicon glass (BSG), tetraethylorthosilicate (TEOS) oxide, and/or other applicable dielectric materials In some embodiments, the dielectric layer 210 is formed by chemical vapor deposition (CVD), physical vapor deposition, (PVD), atomic layer deposition (ALD) or other applicable deposition processes.

The conductive plate 220-1 is disposed over the P-type semiconductor substrate 200 and overlaps the isolation feature 204 between the N-type well region NW and the P-type well region PW. In some embodiments, the conductive plate 220 is disposed directly above the P-type well region PW without extending over the N-type well region NW. In addition, the conductive plate 220 may be separated from the isolation feature 204 by the dielectric layer 210. In some embodiments, the conductive plate 220-1 is formed without overlapping any conductive feature (if exists) between the isolation feature 204 and the conductive plate 220-1. In some embodiments, the conductive plate 220-1 includes electrically conductive material, such as copper (Cu), tungsten (W), aluminum (Al), titanium (Ti), tantalum (Ta), cobalt (Co), other suitable conductive materials, or combinations thereof.

In some embodiments, a projection 220-1P of the conductive plate 220-1 on a top surface 204T of the isolation feature 204 is completely located within the isolation feature 204 directly above the P-type well region PW. In some embodiments, the projection 220-1P of the conductive plate 220-1 is separated from the second N-type doped region N2.

In some embodiments, the first N-type doped region N1 (including all the first N-type doped regions N1 in FIGS. 2C and 2D) and the conductive plate 220-1 are electrically connected to a power-supply terminal VDD. The second N-type doped region N2 (including all the second N-type doped region N2 in FIGS. 2C and 2D) and the first P-type doped region P1 are electrically connected to a ground terminal VSS.

In some embodiments, the N-type well region NW, the P-type well region PW, the first N-type doped region N1, the second N-type doped region N2, the first P-type doped region P1, the isolation feature 204 between the N-type well region NW and the P-type well region PW, the conductive plate 220-1 and a portion of the dielectric layer 210 between the isolation feature 204 and the conductive plate 220-1 may collectively form an N-type field-oxide field-effect transistor (FOXFET) 250. In the N-type FOXFET 250, the conductive plate 220-1 may serve as a gate electrode 220-1, the portion of the dielectric layer 210 between the isolation feature 204 and the conductive plate 220-1 may serve as a gate dielectric, the first N-type doped region N1 and the second N-type doped region N2 may serve as N-type source/drain doped regions N1 and N2, and the first P-type doped region P1 may serve as a bulk doped region P1. In this embodiment, the gate electrode 220-1 and the N-type source/drain doped region N1 of the N-type FOXFET 250 are electrically connected to the power-supply terminal VDD. In addition, the N-type source/drain doped region N2 and the P-type bulk doped region are electrically connected to the ground terminal VSS.

FIGS. 3 and 4 also shows an equivalent discharge circuit diagrams of the ESD protection devices 500A, 500A′, 500B and 500B′ when an electrostatic discharge (ESD) event occurs between the power-supply terminal VDD and the ground terminal VSS. Furthermore, FIGS. 3 and 4 shows parasitic elements of an equivalent discharge circuit at the corresponding positions of the ESD protection devices 500A, 500A′, 500B and 500B′. As shown in FIGS. 3 and 4, the first N-type doped region N1, the P-type well region PW and the second N-type doped region N2 form a parasitic bipolar junction transistor (BJT) B1 (such as a parasitic NPN BJT). Collector, base and emitter of the parasitic bipolar junction transistor B1 are respectively formed by the first N-type doped region N1, the P-type well region PW and the second N-type doped region N2. Moreover, the base (the P-type well region PW) and the emitter (the second N-type doped region N2) of the parasitic bipolar junction transistor B1 are electrically connected to the ground terminal VSS. The collector (first N-type doped region N1) of the parasitic bipolar junction transistor B1 is electrically connected to the power-supply terminal VDD.

When an electrostatic discharge event occurs between the power-supply terminal VDD and the ground terminal VSS, the parasitic bipolar junction transistor B1 is triggered to ON to form a current path PH1 from the power-supply terminal VDD, through the first N-type doped region N1, the N-type well region NW, the P-type well region PW the second N-type doped region N2 and to the ground terminal VSS in order to discharge the electrostatic charges away from the internal circuit 400 (FIG. 1).

In some embodiments, the first N-type doped region N1 and the conductive plate 220-1 are both electrically connected to the power-supply terminal VDD. When an electrostatic discharge event occurs from the power-supply terminal VDD to the ground terminal VSS (e.g., the positive-mode ESD), the power-supply terminal VDD and the conductive plate 220-1 are at high voltage level, an electric field would be generated between the conductive plate 220-1 and the isolation feature 204 between the N-type well region NW and the P-type well region PW. In addition, the electric field may increase in proportion to the ESD clamping voltage (i.e., the voltage drop across the ESD device 500A/500B during an ESD event occurring from the power-supply terminal VDD to the ground terminal VSS). Therefore, electrons of the ESD discharging current in the channel region (a region of the P-type semiconductor substrate 200 between the first N-type doped region N1 and the second N-type doped region N2 and under the isolation feature 204 between the N-type well region NW and the P-type well region PW) of the N-type FOXFET 250 (in other words, electrons of the ESD discharging current between the collector and the emitter of the parasitic bipolar junction transistor) may be attracted towards the bottom 204B of the isolation feature 204, the current path PH1 between the first N-type doped region N1 to the second N-type doped region N2 can be shortened, the on-resistance (Ron) of the N-type FOXFET 250 can be further reduced. Accordingly, the ESD protection device 500A/500A′/500B/500B′ may have low trigger voltage, low holding voltage (V_{Hold}) and low on-resistance (Ron).

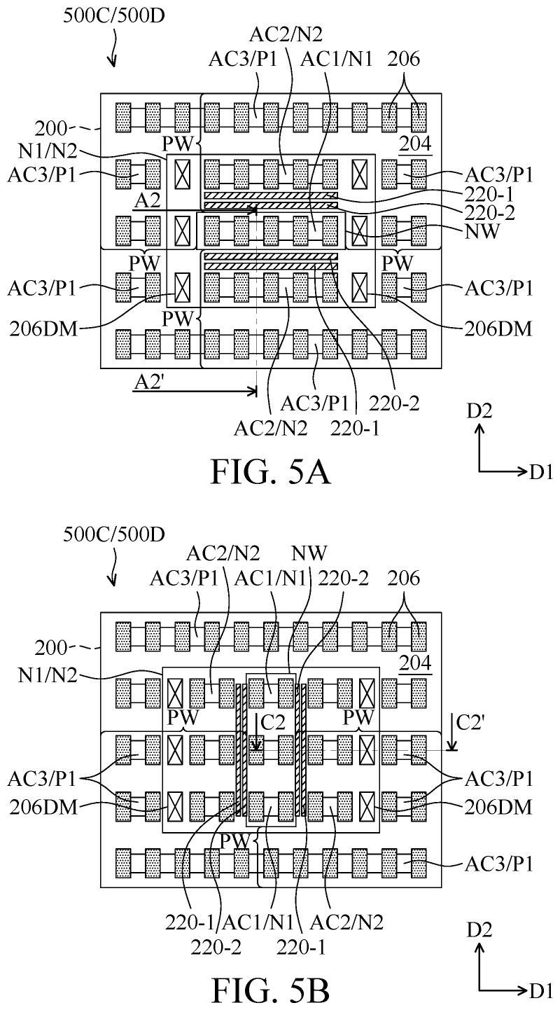

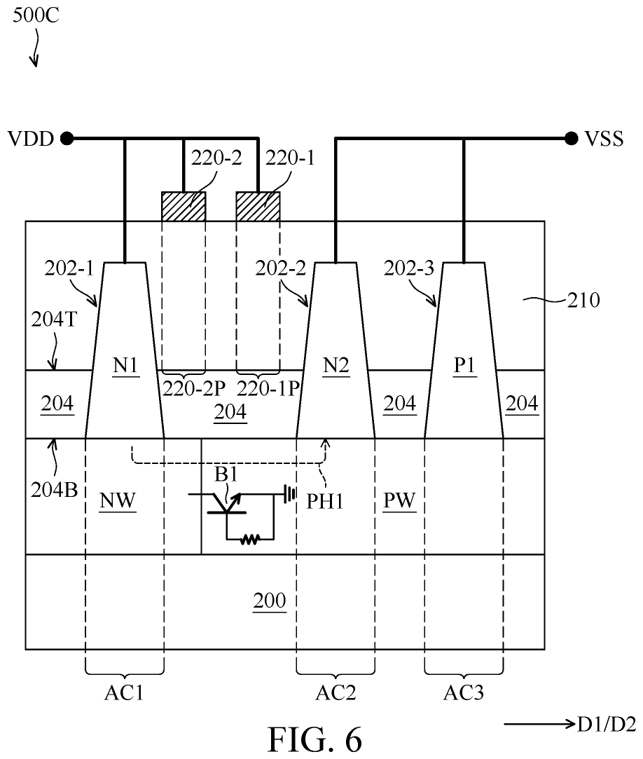

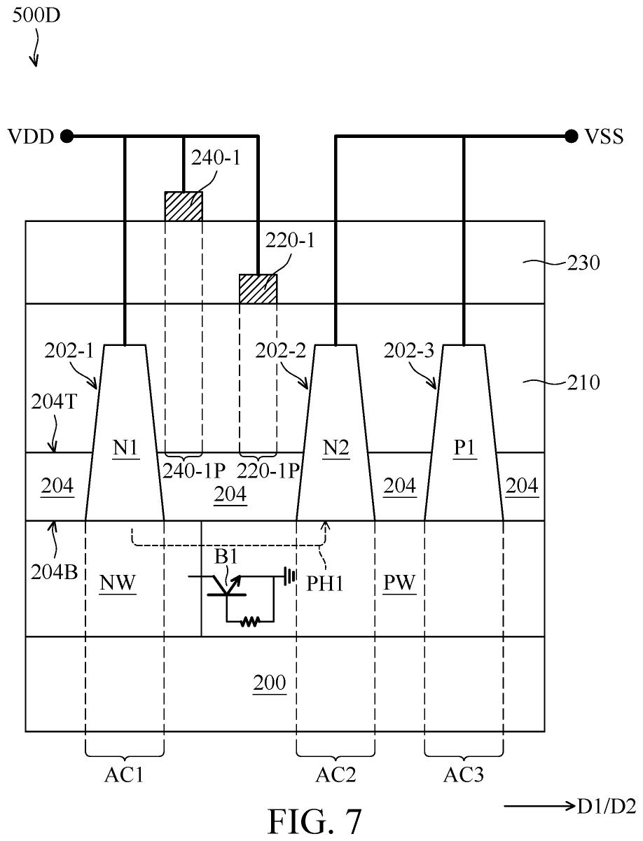

In some embodiments, the electrostatic discharge protection device 500 may include a plurality of separated conductive plates directly above the isolation feature 204 between the N-type well region NW and the P-type well region PW. The separated conductive plates may collectively serve as the gate electrode of the FOXFET 250 of the ESD protection device 500. In addition, the separated conductive plates electrically connected to the power-supply terminal VDD may help to adjust the electric field generated between the conductive plates and the isolation feature 204 and increase design flexibility. In some embodiments, the separated conductive plates may be located at the same levels or different levels. FIG. 5A is a schematic layout of the electrostatic discharge protection device 500C/500D of FIG. 1 in accordance with some embodiments of the disclosure. FIG. 5B is another schematic layout of the electrostatic discharge protection device 500C/500D of FIG. 1 in accordance with some embodiments of the disclosure. FIGS. 5A and 5B may also serve as schematic plane views of the electrostatic discharge protection device 500C/500D in accordance with some embodiments of the disclosure. FIGS. 6 and 7 are schematic cross-sectional views of the electrostatic discharge protection devices 500C, 500D along lines A2-A2′ and C2-C2′ of FIGS. 5A and 5B in accordance with some embodiments of the disclosure. Elements of the embodiments hereinafter, that are the same or similar as those previously described with reference to FIGS. 1, 2A, 2B, 2C, 2D, 3 and 4, are not repeated for brevity. It is noted that the ESD protection devices 500C, 500D fabricated by the fin field-effect transistor (finFET) processes are merely examples and are not limited to the disclosed embodiments. In various embodiments, the ESD protection devices 500C, 500D are fabricated by the planar metal-oxide-semiconductor field-effect transistor (MOSFET) processes.

As shown in FIGS. 5A, 5B and 6, the difference between the ESD protection device 500A/500B (or the ESD protection device 500A′/500B′) and the ESD protection device 500C is that the ESD protection device 500C further includes a conductive plate 220-2 disposed beside the conductive plate 220-1 and overlapping the isolation feature 204 between the N-type well region NW and the P-type well region PW. In some embodiments, the conductive plate 220-2 is arranged parallel to the conductive plate 220-1 and electrically connected to the power-supply terminal VDD. As shown in FIG. 6, the conductive plates 220-1 and 220-2 may be located at the same level. For example, the conductive plates 220-1 and 220-2 are located on and in contact with the dielectric layer 210.

In some embodiments as shown in FIG. 6, the conductive plate 220-2 may be located directly above the P-type well region PW and/or the N-type well region NW. A projection 220-2P of the conductive plate 220-2 may be located on the top surface 204T of the isolation feature is completely located within the isolation feature 204 between the P-type well region PW and the N-type well region NW. In addition, the projection 220-2P of the conductive plate 220-2 may be separated from the N-type doped region N2. In some embodiments, the projection 220-1P of the conductive plate 220-1 is separated from the projection 220-2P of the conductive plate 220-2. In some other embodiments, the conductive plate 220-2 may extend to overlap the first N-type doped region N1. The projection 220-2P of the conductive plate 220-2 may extend from the isolation feature 204 directly above the P-type well region PW to overlapping the first N-type doped region N1.

As shown in FIG. 7, the difference between the ESD protection device 500A/500B (or the ESD protection device 500A′/500B′) and the ESD protection device 500D is that the ESD protection device 500D further includes a conductive plate 240-1 disposed overlapping the isolation feature 204 between the N-type well region NW and the P-type well region PW. In some embodiments, the conductive plate 240-1 is arranged parallel to the conductive plate 220-1 and electrically connected to the power-supply terminal VDD. As shown in FIG. 7, the conductive plates 220-1 and 240-1 are located at different levels. For example, the conductive plate 240-1 may be disposed on the dielectric layer 230 covering the conductive plate 220-1. In some embodiments, the dielectric layer 230 may serve as an intermetal dielectric (IMD) layer 230. In some embodiments, the conductive plates 220-1 and 240-1 may include the same or similar materials.

In some embodiments as shown in FIG. 7, the conductive plate 240-1 may be located directly above the P-type well region PW and/or the N-type well region NW. A projection 240-1P of the conductive plate 240-1 may be located on the top surface 204T of the isolation feature is completely located within the isolation feature 204 between the P-type well region PW and the N-type well region NW. In addition, the projection 240-1P of the conductive plate 240-1 may be separated from the N-type doped region N2. In some embodiments, the projection 220-1P of the conductive plate 220-1 is separated from the projection 240-1P of the conductive plate 240-1. In some other embodiments, the projection 220-1P of the conductive plate 220-1 may overlap the projection 240-1P of the conductive plate 240-1. It should be appreciated that although some features are shown in some embodiments but not in other embodiments, these features may (or may not) exist in other embodiments whenever possible. For example, although each of the illustrated exemplary embodiments shows specific arrangements of the conductive plates 220-1 and 240-1, any other combinations of arrangements of the conductive plates may also be used whenever applicable. In addition, other combinations of the conductive plates 220-1 and 220-2 of the ESD protection device 500C may be implemented in the ESD protection device 500D whenever applicable.

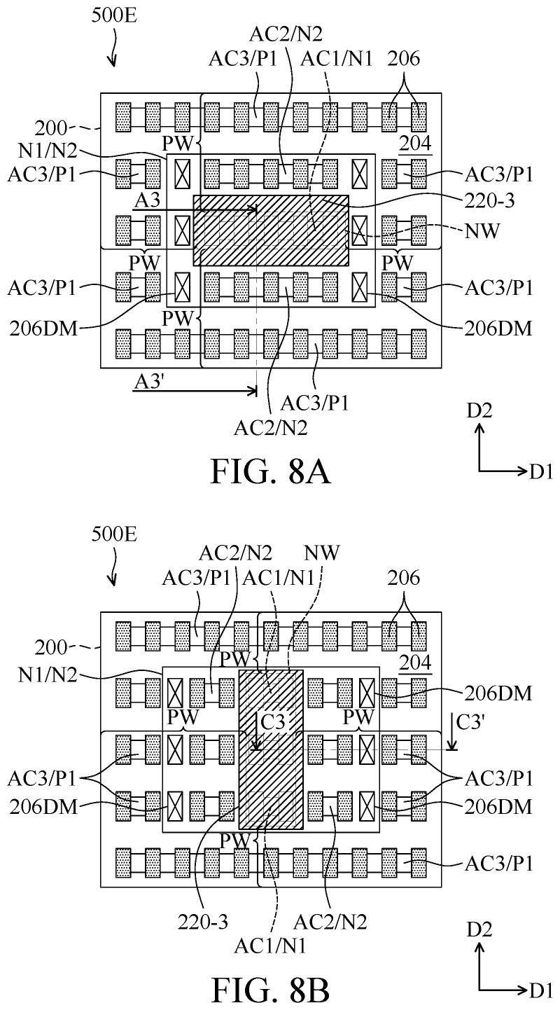

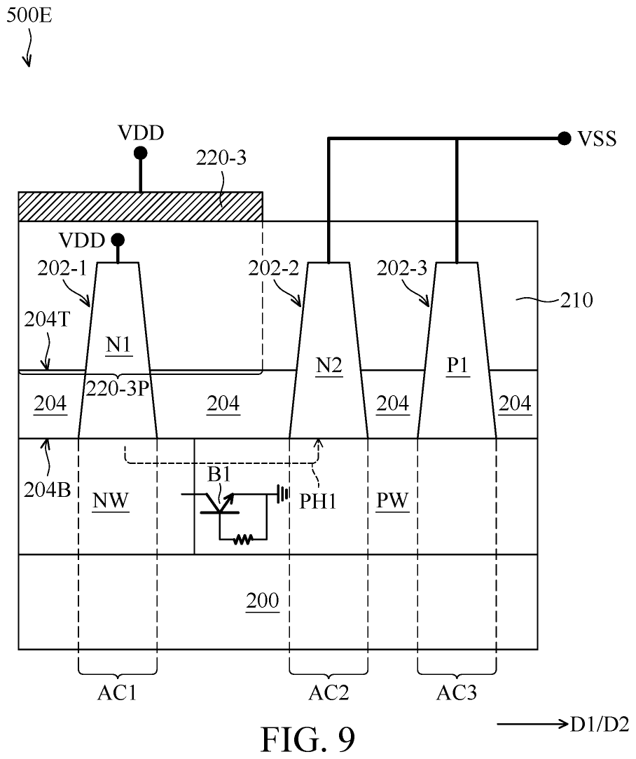

In some embodiments, a projection of the conductive plate (also serves as the gate electrode of the FOXFET 250) on the top surface 204T of the isolation feature 204 may extend to overlap the first N-type doped region N1 to achieve the described advantages and increase design flexibility. FIG. 8A is a schematic layout of the electrostatic discharge protection device 500E of FIG. 1 in accordance with some embodiments of the disclosure. FIG. 8B is a schematic layout of the electrostatic discharge protection device 500E of FIG. 1 in accordance with some embodiments of the disclosure. FIGS. 8A and 8B may also serve as schematic plane views of the electrostatic discharge protection device 500E of FIG. 1 in accordance with some embodiments of the disclosure. FIG. 9 are schematic cross-sectional views of the electrostatic discharge protection device 500E along lines A3-A3′ and C3-C3′ of FIGS. 8A and 8B in accordance with some embodiments of the disclosure. Elements of the embodiments hereinafter, that are the same or similar as those previously described with reference to FIGS. 1, 2A, 2B, 2C, 2D, 3, 4, 5A, 5B, 6 and 7, are not repeated for brevity. It is noted that the ESD protection device 500E fabricated by the fin field-effect transistor (finFET) processes is merely examples and are not limited to the disclosed embodiments. In various embodiments, the ESD protection device 500E is fabricated by the planar metal-oxide-semiconductor field-effect transistor (MOSFET) processes.

As shown in FIGS. 8A, 8B and 9, the difference between the ESD protection device 500A/500B (or the ESD protection device 500A′/500B) and the ESD protection device 500E is that of the ESD protection device 500E further includes a conductive plate 220-3 directly above the isolation feature 204 between the P-type well region PW and the N-type well region NW and extending to overlap the first N-type doped region N1 and the N-type well region NW. In addition, the conductive plate 220-3 may be electrically connected to the power-supply terminal VDD. In some embodiments, a projection 220-3P of the conductive plate 220-3 on the top surface 204T of the isolation feature 204 may extend to overlap the first N-type doped region N1 and the N-type well region NW. It should be appreciated that although some features are shown in some embodiments but not in other embodiments, these features may (or may not) exist in other embodiments whenever possible. For example, although each of the illustrated exemplary embodiments shows specific arrangements of the conductive plate 220-3, any other combinations of arrangements of the conductive plates may also be used whenever applicable. In addition, other combinations of the conductive plates 220-1, 220-2 and 240-1 of the ESD protection devices 500C and 500D may be implemented in the ESD protection device 500E whenever applicable.

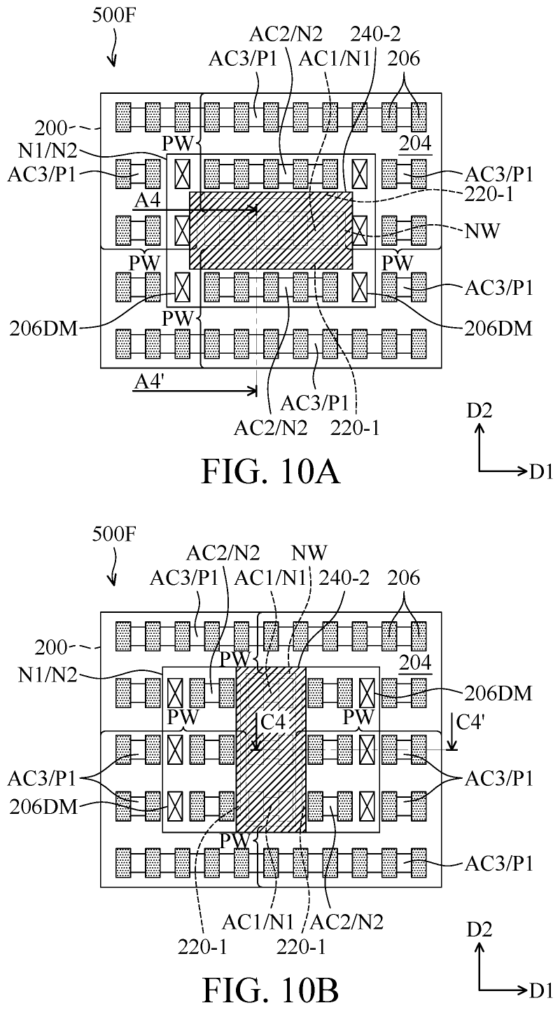

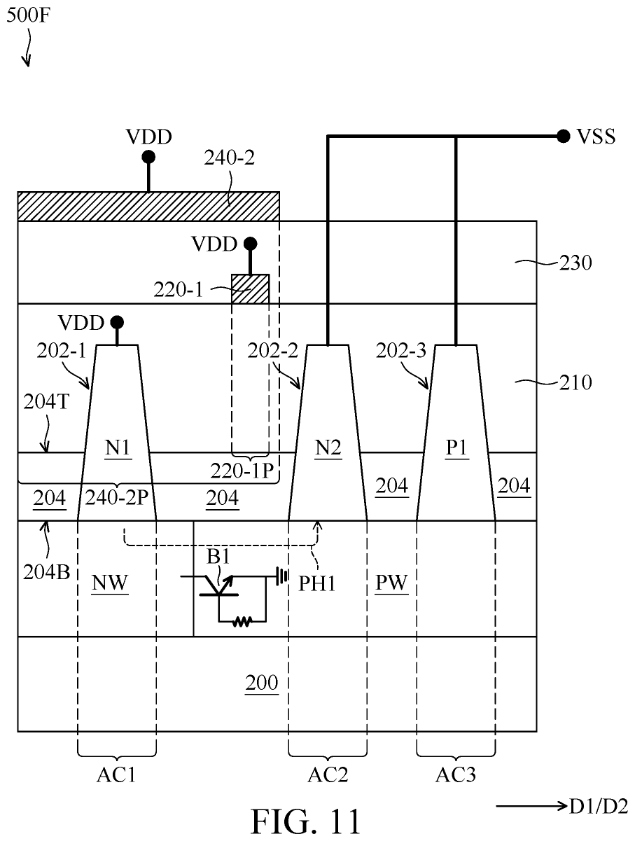

In some embodiments, when the ESD protection devices 500 includes separated conductive plates located at different levels (collectively serve as gate electrode of the FOXFET 250). At least one of the separated conductive plates may extend to overlap the first N-type doped region N1 to achieve the described advantages and increase design flexibility. FIG. 10A is a schematic layout of the electrostatic discharge protection device 500F in accordance with some embodiments of the disclosure. FIG. 10B is another schematic layout of the electrostatic discharge protection device 500F of FIG. 1 in accordance with some embodiments of the disclosure. FIGS. 10A and 10B may also serve as schematic plane views of the electrostatic discharge protection device 500F in accordance with some embodiments of the disclosure. FIG. 11 are schematic cross-sectional views of the electrostatic discharge protection device 500F along lines A4-A4′ and C4-C4′ of FIGS. 10A and 10B in accordance with some embodiments of the disclosure. Elements of the embodiments hereinafter, that are the same or similar as those previously described with reference to FIGS. 1, 2A, 2B, 2C, 2D, 3, 4, 5A, 5B, 6, 7, 8A, 8B and 9, are not repeated for brevity. It is noted that the ESD protection device 500F fabricated by the fin field-effect transistor (finFET) processes is merely examples and are not limited to the disclosed embodiments. In various embodiments, the ESD protection device 500F is fabricated by the planar metal-oxide-semiconductor field-effect transistor (MOSFET) processes.

As shown in FIGS. 10A, 10B and 11, the difference between the ESD protection device 500D (FIG. 7) and the ESD protection device 500F is that of the ESD protection device 500F further includes a conductive plate 240-2 directly above the conductive plate 220-1 and the isolation feature 204 between the P-type well region PW and the N-type well region NW. In addition, the conductive plate 240-2 may be electrically connected to the power-supply terminal VDD. In some embodiments, the conductive plate 240-2 may extend to overlap the first N-type doped region N1. A projection 240-2P of the conductive plate 240-2 on the top surface 204T of the isolation feature 204 may extend from the isolation feature 204 directly above the P-type well region PW to overlap the first N-type doped region N1. In some embodiments, the projection 240-2P of the conductive plate 240-2 overlaps the projection 220-1P of the conductive plate 220-1 and the first N-type doped region N1. It should be appreciated that although some features are shown in some embodiments but not in other embodiments, these features may (or may not) exist in other embodiments whenever possible. For example, although each of the illustrated exemplary embodiments shows specific arrangements of the conductive plates 220-1 and 240-2, any other combinations of arrangements of the conductive plates may also be used whenever applicable. In addition, other combinations of the conductive plates 220-1, 220-2, 220-3 and 240-1 of the ESD protection devices 500C to 500E may be implemented in the ESD protection device 500F whenever applicable.

Embodiments provide an electrostatic discharge (ESD) protection device. The ESD protection device includes a P-type semiconductor substrate, adjacent N-type and P-type well regions in the P-type semiconductor substrate, first and second N-type doped regions on the N-type and P-type well regions, a first P-type doped region on the P-type well region, an isolation feature between the N-type and P-type well regions and a conductive plate directly above the isolation feature and the P-type well region. The N-type and P-type well regions, the first N-type and second N-type doped regions, the first P-type doped region, the isolation feature and the conductive plate directly above the isolation feature and the P-type well region may collectively formed an N-type field oxide field-effect transistor (N-type FOXFET). In the N-type FOXFET, the conductive plate may serve as a gate electrode, the portion of a dielectric layer between the isolation feature and the conductive plate may serve as a gate dielectric. The first and second N-type doped regions may serve as first and second N-type source/drain doped regions, and the first P-type doped region may serve as a bulk doped region. In addition, the first N-type doped region, the P-type well region and the second N-type doped region may form a parasitic bipolar junction transistor (BJT) (such as a parasitic NPN BJT). The base (the P-type well region) and the emitter (the second N-type doped region) of the parasitic bipolar junction transistor are electrically connected to a ground terminal (GND). The collector (the first N-type doped region) of the parasitic bipolar junction transistor is electrically connected to a power-supply terminal (VDD).

When an electrostatic discharge event occurs from the power-supply terminal VDD to the ground terminal VSS (e.g., the positive-mode ESD), the parasitic bipolar junction transistor is triggered to ON to discharge the electrostatic charges away from the internal circuit. In addition, an electric field would be generated between the conductive plate and the isolation feature between the collector and the emitter of the parasitic bipolar junction transistor. Therefore, electrons of the ESD discharging current in the channel region of the N-type FOXFET may be attracted towards the bottom of the isolation feature, the discharging current path between the first N-type doped region to the second N-type doped region can be shortened, the on-resistance (Ron) of the N-type FOXFET can be further reduced. Accordingly, the ESD protection device may have low trigger voltage, low holding voltage (V_{Hold}) and low on-resistance (Ron). In some embodiments, the conductive plate may extend to overlap the first N-type doped region. In some embodiments, the electrostatic discharge protection device may include a plurality of separated conductive plates directly above the isolation feature between the collector and the emitter of the parasitic bipolar junction transistor. In addition, the separated conductive plates electrically connected to the power-supply terminal VDD may help to adjust the electric field generated between the conductive plates and the isolation feature and increase design flexibility. In some embodiments, the separated conductive plates may be at the same levels or different levels.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge protection device, comprising:
a P-type semiconductor substrate;
an N-type well region located in the P-type semiconductor substrate;
a first N-type doped region located on the N-type well region;
a P-type well region located in the P-type semiconductor substrate and adjacent to the N-type well region;
a second N-type doped region located on the P-type well region, wherein the first N-type doped region is spaced apart from the second N-type doped region by an isolation feature;
a first P-type doped region located on the P-type well region, wherein the first P-type doped region and the second N-type doped region are spaced apart from each other; and
a first conductive plate disposed overlapping the isolation feature;
wherein the first N-type doped region and the first conductive plate are electrically connected to a power-supply terminal, and
wherein the second N-type doped region and the first P-type doped region are electrically connected to a ground terminal.

2. The electrostatic discharge protection device as claimed in claim 1, wherein a first projection of the first conductive plate on a top surface of the isolation feature is completely located within the isolation feature directly above the P-type well region.

3. The electrostatic discharge protection device as claimed in claim 2, wherein the first projection of the first conductive plate is separated from the second N-type doped region.

4. The electrostatic discharge protection device as claimed in claim 1, wherein a first projection of the first conductive plate on a top surface of the isolation feature extends to overlap the first N-type doped region.

5. The electrostatic discharge protection device as claimed in claim 2, further comprising:
a second conductive plate disposed overlapping the isolation feature, wherein the second conductive plate is electrically connected to the power-supply terminal.

6. The electrostatic discharge protection device as claimed in claim 1, wherein the first conductive plate and the second conductive plate are located at the same level.

7. The electrostatic discharge protection device as claimed in claim 1, wherein the first conductive plate and the second conductive plate are located at different levels.

8. The electrostatic discharge protection device as claimed in claim 5, wherein a second projection of the second conductive plate on the top surface of the isolation feature is completely located within the isolation feature.

9. The electrostatic discharge protection device as claimed in claim 8, wherein the first projection is separated from the second projection.

10. The electrostatic discharge protection device as claimed in claim 5, wherein a second projection of the second conductive plate on the top surface of the isolation feature extends to overlap the first N-type doped region.

11. The electrostatic discharge protection device as claimed in claim 10, wherein the first projection overlaps the second projection.

12. The electrostatic discharge protection device, as claimed in claim 1, further comprising:
a first fin, a second fin and a third fin protruding from the P-type semiconductor substrate and parallel to one another, wherein the first fin and the second fin are located on opposite sides of the isolation feature, and
wherein the first N-type doped region is located in the first fin, the second N-type doped region is located in the second fin, and the first P-type doped region is located in the third fin.

13. The electrostatic discharge protection device as claimed in claim 1, wherein:
the first N-type doped region, the P-type well region and the second N-type doped region form a parasitic bipolar junction transistor,
wherein a base and an emitter of the parasitic bipolar junction transistor is electrically connected to the ground terminal, and
wherein a collector of the parasitic bipolar junction transistor is electrically connected to the power-supply terminal.

14. The electrostatic discharge protection device as claimed in claim 1, wherein the first conductive plate is separated from the isolation feature by a dielectric layer.

15. An electrostatic discharge protection device, comprising:
a P-type semiconductor substrate; and
an N-type field oxide field-effect transistor formed on the P-type semiconductor substrate, wherein the field oxide field-effect transistor comprises:
an N-type well region and a P-type well region located in the P-type semiconductor substrate and adjacent to each other;
a first N-type source/drain doped region located on the N-type well region;
a second N-type source/drain doped region located on the P-type well region;
an isolation feature located in the P-type semiconductor substrate and between the first N-type source/drain doped region and the second N-type source/drain doped region;
a gate electrode comprising a first conductive plate disposed directly above the isolation feature and the P-type well region; and
a P-type bulk doped region located on the P-type well region and spaced apart from the second N-type source/drain doped region;
wherein the first N-type source/drain doped region is electrically connected to the gate electrode, and
wherein the second N-type source/drain doped region is electrically connected to the P-type bulk doped region.

16. The electrostatic discharge protection device as claimed in claim 15, further comprising:
a first fin, a second fin and a third fin protruding from the P-type semiconductor substrate and parallel to one another,
wherein the first N-type source/drain doped region is located in the first fin, the second N-type source/drain doped region is located in the second fin, and the first P-type bulk doped region is located in the third fin.

17. The electrostatic discharge protection device as claimed in claim 15, wherein the first conductive plate is electrically connected to a power-supply terminal, and the P-type bulk doped region is electrically connected to a ground terminal.

18. The electrostatic discharge protection device as claimed in claim 17, wherein the first conductive plate extends to overlap the first N-type source/drain doped region.

19. The electrostatic discharge protection device as claimed in claim 15, wherein the gate electrode further comprises:
a second conductive plate disposed overlapping the isolation feature, wherein the second conductive plate is electrically connected to a power-supply terminal.

20. The electrostatic discharge protection device as claimed in claim 15, wherein:
the first N-type source/drain doped region, the P-type well region and the second N-type source/drain doped region form a parasitic bipolar junction transistor,
wherein a base and an emitter of the parasitic bipolar junction transistor is electrically connected to a ground terminal, and
wherein a collector of the parasitic bipolar junction transistor is electrically connected to a power-supply terminal.
